(19) United States
(12) Patent Application Publication
(10) Pub. No.: US 2018/0021804 A1
(43) Pub. Date: Jan. 25, 2018

(54) COATING TREATMENT METHOD, COMPUTER STORAGE MEDIUM, AND COATING TREATMENT APPARATUS

(71) Applicant: Tokyo Electron Limited, Tokyo (JP)

(72) Inventors: Takafumi HASHIMOTO, Koshi City, Kumamoto (JP); Shinichi HATAKEYAMA, Koshi City, Kumamoto (JP); Naoki SHIBATA, Koshi City, Kumamoto (JP); Kousuke YOSHIHARA, Koshi City, Kumamoto (JP)

(21) Appl. No.: 15/549,435

(22) PCT Filed: Feb. 4, 2016
(86) PCT No.: PCT/JP2016/053335

§ 371 Date: Aug. 8, 2017

(30) Foreign Application Priority Data
Mar. 3, 2015 (JP) 2015-041679

(51) Int. Cl. B05D 1/00; B05D 3/10; H01L 21/027; H01L 21/67

(52) U.S. Cl. CPC B05D 1/005; H01L 21/6715; B05D 3/104; H01L 21/027; H01L 21/67253

(57) ABSTRACT

A coating treatment method of applying a coating solution onto a substrate, includes: a solvent liquid film formation step of forming a first liquid film of a solvent at a middle portion of the substrate and forming a ring-shaped second liquid film having a film thickness larger than a film thickness of the first liquid film of the solvent at an outer peripheral portion of the substrate; a coating solution supply step of supplying the coating solution to a center portion of the substrate while rotating the substrate at a first rotation speed; and a coating solution diffusion step of diffusing the coating solution on the substrate by rotating the substrate at a second rotation speed higher than the first rotation speed while supplying the coating solution.

### CROSS REFERENCE TO RELATED APPLICATIONS

This application is based upon and claims the benefit of priority of the prior Japanese Patent Application No. 2015-041679, filed in Japan on Mar. 3, 2015, the entire contents of which are incorporated herein by reference.

### TECHNICAL FIELD

The present invention relates to a coating treatment method of applying a coating solution to a substrate, a computer storage medium, and a coating treatment apparatus.

### BACKGROUND ART

In a photolithography process in a manufacturing process of a semiconductor device, for example, a coating treatment of applying a predetermined coating solution, for example, onto a semiconductor wafer (hereinafter, referred to as a “wafer”) as a substrate to form a coating film such as an anti-reflection film, a resist film or the like, exposure processing of exposing the resist film into a predetermined pattern, a developing treatment of developing the exposed resist film, and so on are sequentially performed to form a predetermined resist pattern on the wafer.

In the above-descried coating treatment, a so-called spin coating method is often used which supplies the coating solution from a nozzle onto a center portion of the wafer under rotation, and diffuses the coating solution on the wafer by centrifugal force to form a coating film over the wafer.

However, in the coating treatment of an expensive coating solution like a resist solution, the supply amount needs to be reduced as much as possible, but when the supply amount is decreased, the in-plane uniformity of the coating film deteriorates. Hence, for the in-plane uniformity of the coating film and for the reduction in amount of the coating solution used, a so-called pre-wet treatment of applying a solvent such as a thinner onto the wafer before supply of the coating solution to thereby improve the wettability of the wafer is performed (Patent Document 1).

In the case of performing the pre-wet treatment, the solvent is supplied to the center portion of the wafer before the supply of the resist solution, and then the wafer is rotated to diffuse the solvent over the entire surface of the wafer. Subsequently, the rotation speed of the wafer is accelerated up to a predetermined rotation speed, and the resist solution is supplied to the center portion of the wafer and diffused over the entire surface of the wafer.

### PRIOR ART DOCUMENT

### Patent Document

[Patent Document 1] Japanese Laid-open Patent Publication No. 2008-71960

### DISCLOSURE OF THE INVENTION

### Problems to Be Solved by the Invention

Even in the case where the pre-wet treatment is performed, however, if the supply mount of the resist solution is further reduced, the in-plane uniformity of the coating film deteriorates, and therefore there is a limit in reduction of the supply amount of the resist solution.

In particular in the case of using a low-viscosity resist solution having a viscosity of about several cP, the present inventors have confirmed phenomena of the film thickness decreasing at the outer peripheral portion of the wafer and streak-shaped coating mottles occurring if the supply amount is reduced.

The present invention has been made in consideration of the above points, and its object is, when applying a coating solution onto a substrate, to apply the coating solution with a supply amount of the coating solution reduced to a small amount and uniformly within the substrate regardless of the viscosity of the coating solution.

### Means for Solving the Problems

To attain the above object, an aspect of the present invention is a coating treatment method of applying a coating solution onto a substrate, including: a solvent liquid film formation step of forming a first liquid film of a solvent at a middle portion of the substrate and forming a ring-shaped second liquid film having a film thickness larger than a film thickness of the first liquid film of the solvent at an outer peripheral portion of the substrate; a coating solution supply step of supplying the coating solution to a center portion of the substrate while rotating the substrate at a first rotation speed; and a coating solution diffusion step of diffusing the coating solution on the substrate by rotating the substrate at a second rotation speed higher than the first rotation speed while supplying the coating solution.

According to the present inventors, it has been confirmed that when the pre-wet treatment is performed uniformly on the entire surface of the substrate with a solvent, failure such as a decrease in film thickness at the outer peripheral portion of the substrate occurs in particular in the case of using a coating solution having a low viscosity as described above. It is presumed that the failure arises from the fact that pre-wet with the solvent causes, for example, the resist solution as the coating solution to diffuse earlier than expected, and as a result, the resist solution shaken off from the outer peripheral portion of the substrate increases. This tendency becomes more significant as the viscosity of the resist solution becomes lower. Hence, the present inventors earnestly studied this point and have obtained knowledge that the failure such as the decrease in film thickness at the outer peripheral portion of the substrate can be suppressed by making the film thickness of the solvent liquid film at the outer peripheral portion of the substrate larger than that at the middle portion of the substrate. It is considered that the liquid film of the solvent, when formed thick at the outer peripheral portion of the substrate, functions as a kind of wall at the time when the resist solution supplied to the middle portion of the substrate is diffused to the outer peripheral portion of the substrate, and the amount of the resist solution shaken off from the outer peripheral portion of the substrate decreases.

The present invention is based on the above knowledge, and according to an aspect of the present invention, a ring-shaped second liquid film having a film thickness larger than a film thickness of the first liquid film formed at the middle portion of the substrate is formed of the solvent at the outer peripheral portion of the substrate, so that the second liquid film functions as a kind of wall at the time when the coating solution supplied to the center portion of the substrate is diffused to the outer peripheral portion of the substrate, and the amount of the coating solution shaken off from the outer peripheral portion of the substrate decreases. As a result, even if the coating solution is low in viscosity and the supply amount of the coating solution is small, the coating solution can be applied uniformly within the substrate. Therefore, according to the present invention, it is possible to apply the coating solution with a supply amount of the coating solution reduced to a small amount and uniformly within the substrate regardless of the viscosity of the coating solution.

An aspect of the present invention according to another viewpoint is a coating treatment method of applying a coating solution onto a substrate, including: a solvent liquid film formation step of forming a liquid film of a solvent at a middle portion of the substrate and forming another ring-shaped liquid film at an outer peripheral portion of the substrate by forming a liquid film of the solvent by supplying the solvent to the middle portion of the substrate and thereafter rotating the substrate at a predetermined rotation speed to shake off the solvent, and then spraying a dry gas to a position deviated from the middle portion of the substrate with the substrate being rotated to remove the solvent at the position deviated from the middle portion of the substrate; a coating solution supply step of supplying the coating solution to a center portion of the substrate while rotating the substrate at a first rotation speed; and a coating solution diffusion step of diffusing the coating solution on the substrate by rotating the substrate at a second rotation speed higher than the first rotation speed while supplying the coating solution.

An aspect of the present invention according to still another viewpoint is a computer-readable storage medium storing a program running on a computer of a control unit controlling a coating treatment apparatus to cause the coating treatment apparatus to execute the coating treatment method.

An aspect of the present invention according to yet another viewpoint is a coating treatment apparatus for applying a coating solution onto a substrate, including: a substrate holding unit that holds and rotates the substrate; a coating solution supply nozzle that supplies the coating solution onto the substrate; a solvent supply nozzle that supplies a solvent onto the substrate; a first moving mechanism that moves the coating solution supply nozzle; and a second moving mechanism that moves the solvent supply nozzle. The coating treatment apparatus further includes a control unit configured to control the substrate holding unit, the coating solution supply nozzle, the solvent supply nozzle, the first moving mechanism, and the second moving mechanism so as to: form a first liquid film of the solvent at a middle portion of the substrate and form a ring-shaped second liquid film having a film thickness larger than a film thickness of the first liquid film of the solvent at an outer peripheral portion of the substrate; supply the coating solution to a center portion of the substrate while rotating the substrate at a first rotation speed; and diffuse the coating solution on the substrate by rotating the substrate at a second rotation speed higher than the first rotation speed while supplying the coating solution.

### Effect of the Invention

According to the present invention, it is possible, when applying a coating solution onto a substrate, to apply the coating solution with a supply amount of the coating solution reduced to a small amount and uniformly within the substrate regardless of the viscosity of the coating solution.

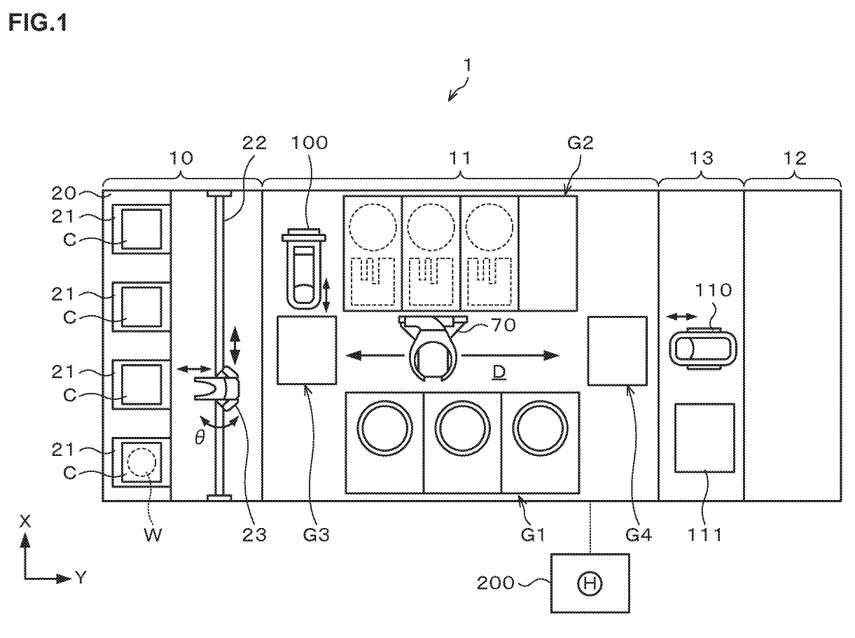

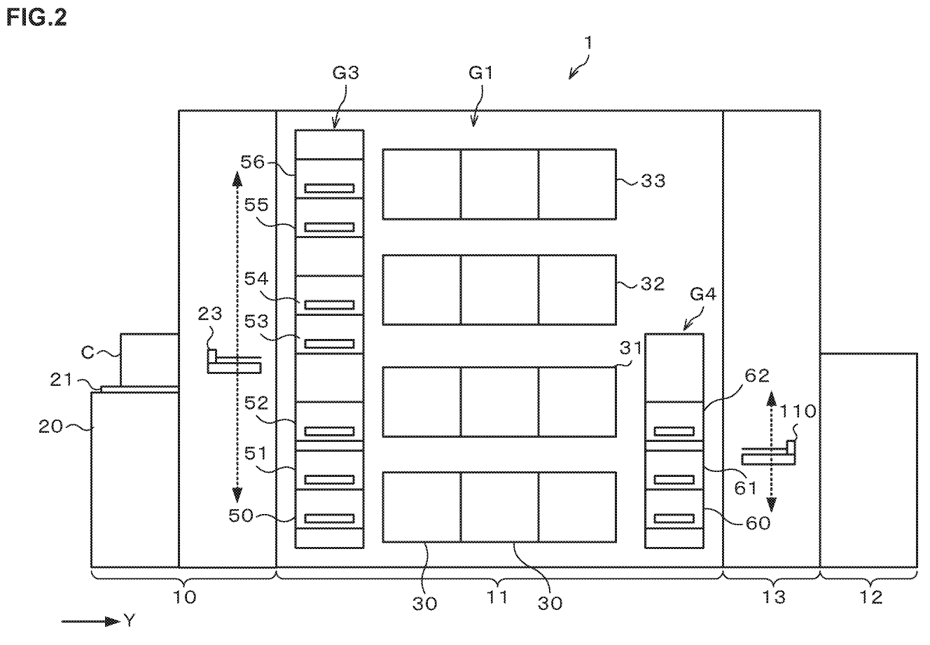

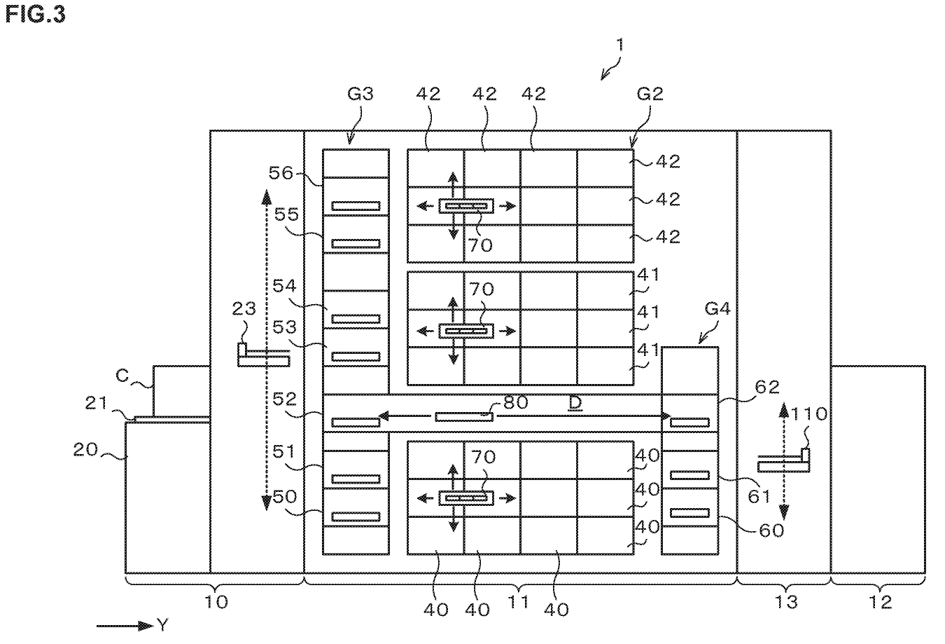

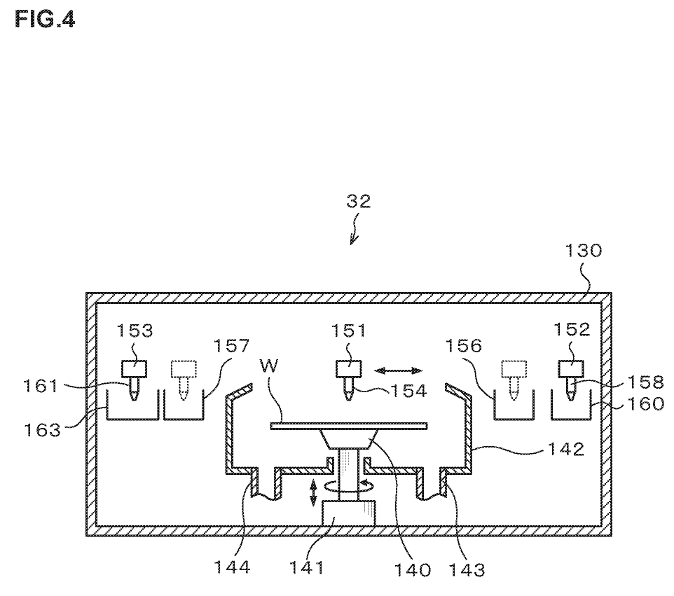

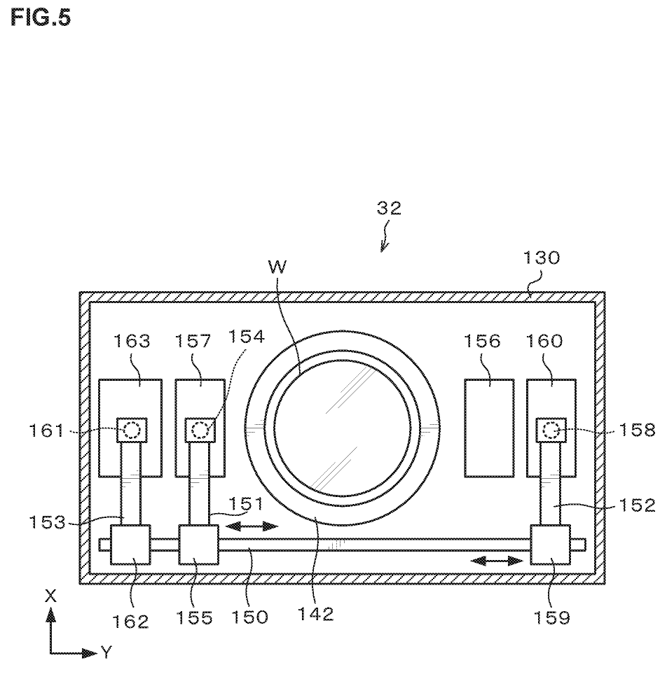

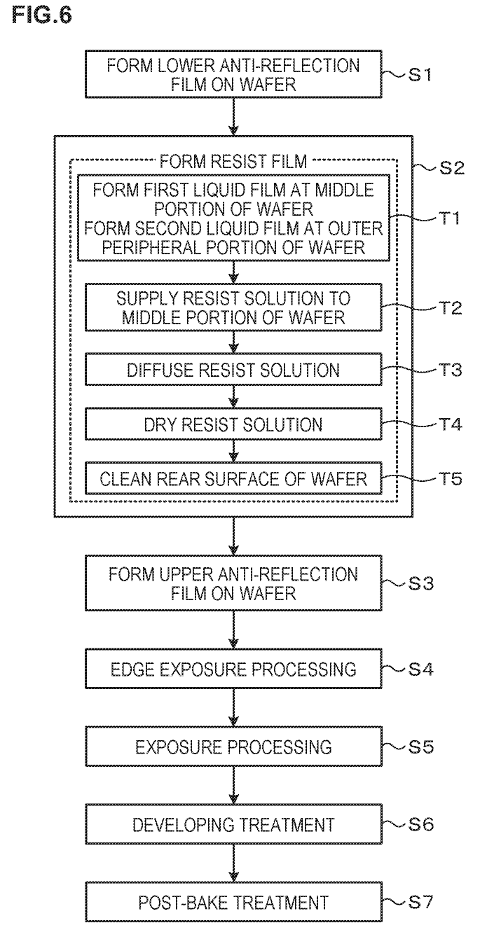

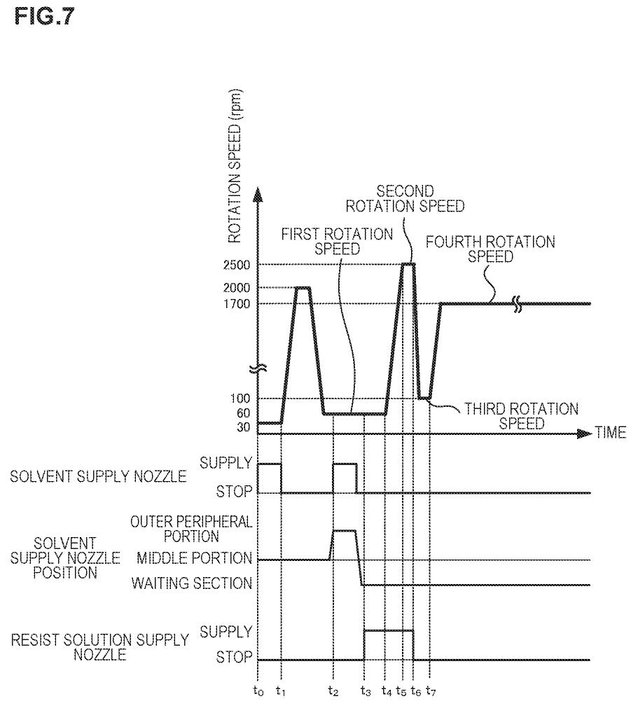

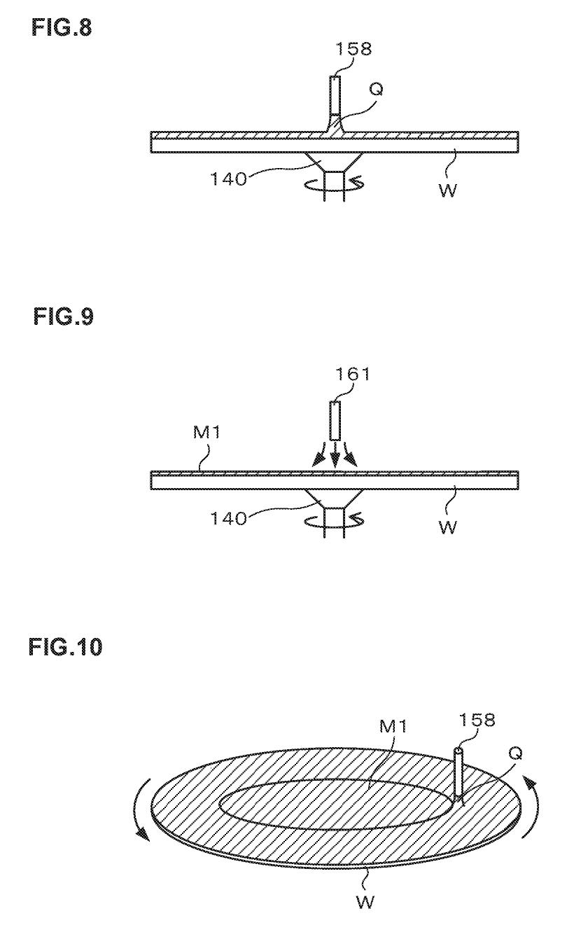

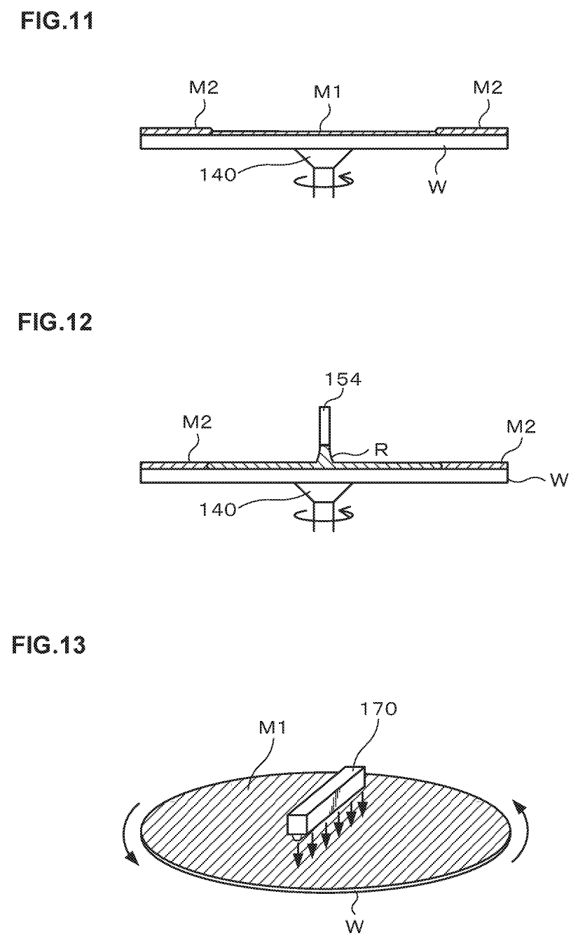

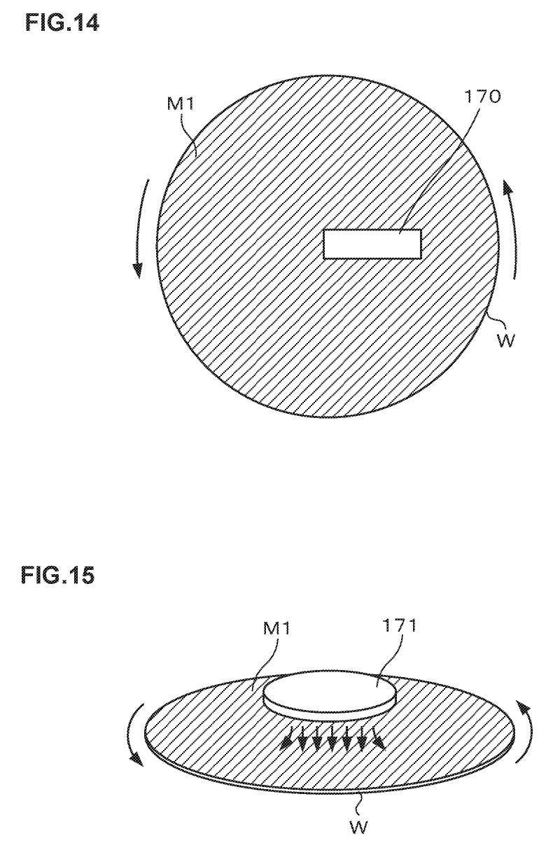

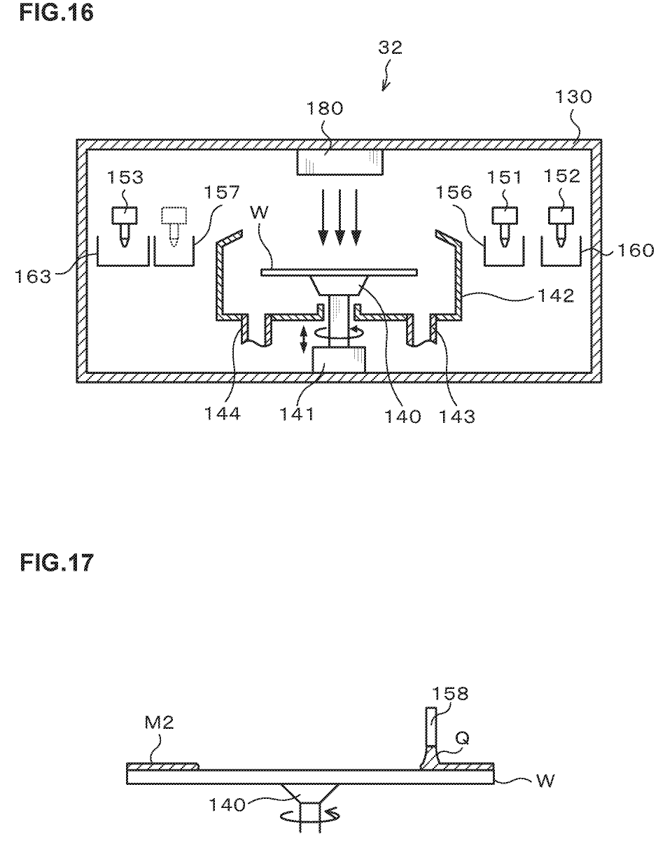

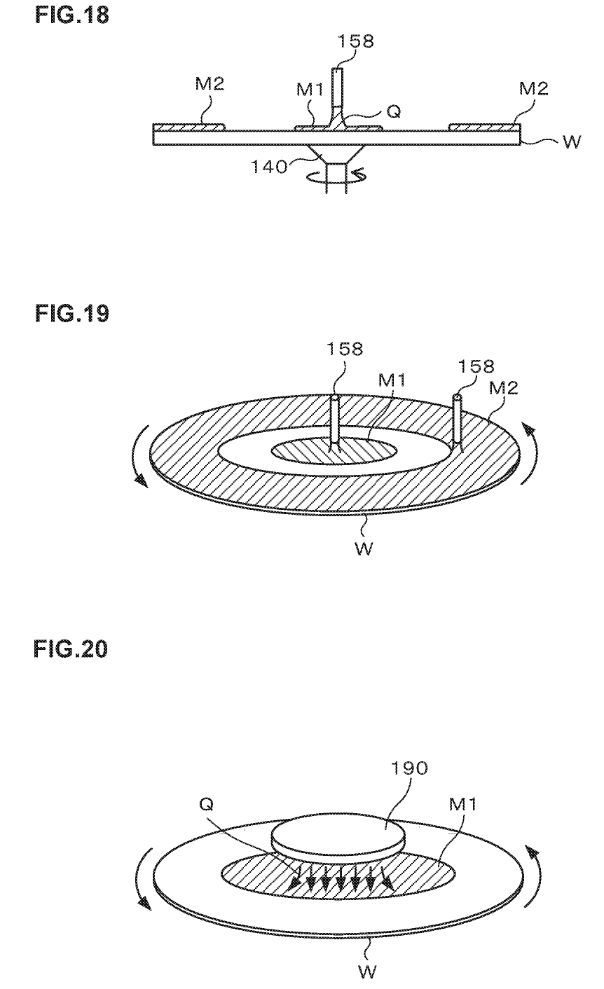

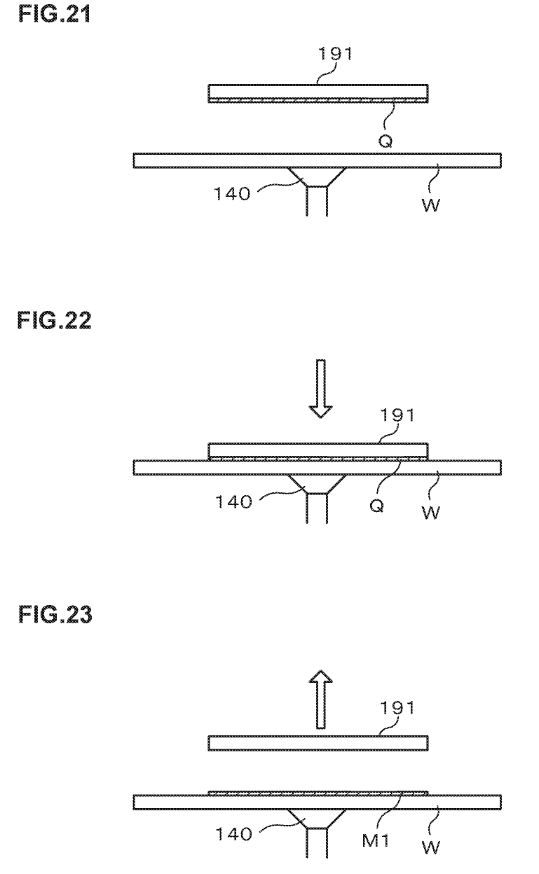

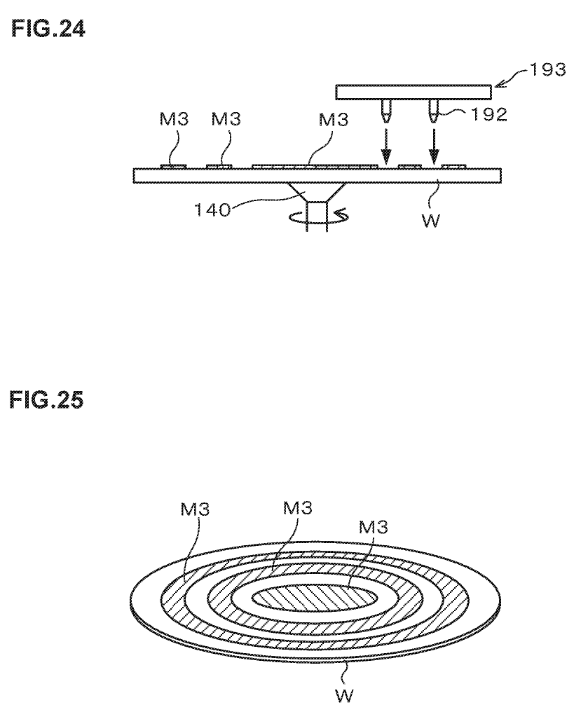

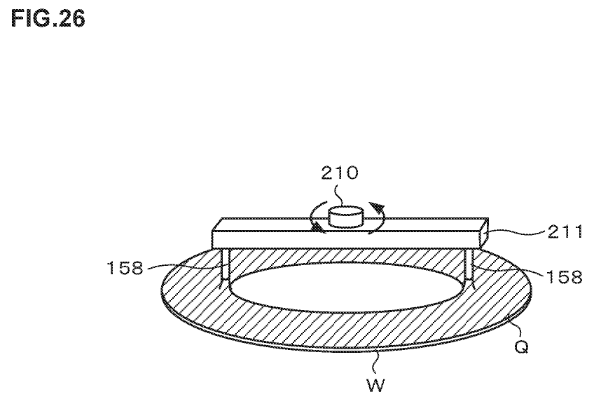

### BRIEF DESCRIPTION OF THE DRAWINGS

[FIG. 1] A plan view illustrating the outline of a configuration of a substrate treatment system according to an embodiment.

[FIG. 2] A front view illustrating the outline of the configuration of the substrate treatment system according to this embodiment.

[FIG. 3] A rear view illustrating the outline of the configuration of the substrate treatment system according to this embodiment.

[FIG. 4] A longitudinal cross-sectional view illustrating the outline of a configuration of a resist coating apparatus.

[FIG. 5] A transverse cross-sectional view illustrating the outline of the configuration of the resist coating apparatus.

[FIG. 6] A flowchart explaining main steps of a wafer treatment.

[FIG. 7] A time chart illustrating the rotation speed of a wafer and operations of devices in a resist coating treatment.

[FIG. 8] An explanatory view of a longitudinal cross-section illustrating an appearance in which a liquid film of a solvent is formed on the wafer.

[FIG. 9] An explanatory view of a longitudinal cross-section illustrating an appearance in which a dry gas is sprayed onto the wafer by a dry gas nozzle.

[FIG. 10] A perspective explanatory view illustrating a state in which a second liquid film is formed by supplying the solvent to an outer peripheral portion of the wafer.

[FIG. 11] An explanatory view of a longitudinal cross-section illustrating a state in which a first liquid film and a second liquid film are formed on the wafer.

[FIG. 12] An explanatory view of a longitudinal cross-section illustrating an appearance in which the resist solution is supplied to the center portion of the wafer and diffused.

[FIG. 13] A perspective explanatory view illustrating an appearance in which the dry gas is sprayed onto the wafer by a dry gas nozzle according to another embodiment.

[FIG. 14] A planar explanatory view illustrating an appearance in which the dry gas is sprayed onto the wafer by a dry gas nozzle according to another embodiment.

[FIG. 15] A perspective explanatory view illustrating an appearance in which the dry gas is sprayed onto the wafer by a dry gas nozzle according to another embodiment.

[FIG. 16] A longitudinal cross-sectional view illustrating the outline of a configuration of a resist coating apparatus according to another embodiment.

[FIG. 17] An explanatory view of a longitudinal cross-section illustrating a state in which the second liquid film is formed by supplying the solvent to the outer peripheral portion of the wafer.

[FIG. 18] An explanatory view of a longitudinal cross-section illustrating a state in which the first liquid film and the second liquid film are formed on the wafer by supplying the solvent to the center portion of the wafer.

[FIG. 19] A perspective explanatory view illustrating an appearance in which the first liquid film and the second liquid film are formed on the wafer in parallel by a plurality of solvent supply nozzles.

[FIG. 20] A perspective explanatory view illustrating a state in which the first liquid film is formed at the middle portion of the wafer by a solvent supply nozzle according to another embodiment.

[FIG. 21] An explanatory view of a longitudinal cross-section illustrating a state in which a template having a liquid film formed thereon is disposed to face the wafer.

[FIG. 22] An explanatory view of a longitudinal cross-section illustrating a state in which the template having the liquid film formed thereon is brought into contact with the wafer.

[FIG. 23] An explanatory view of a longitudinal cross-section illustrating a state in which the first liquid film is formed on the wafer using the template having the liquid film formed thereon.

[FIG. 24] An explanatory view of a longitudinal cross-section illustrating a state in which another liquid film is formed on the wafer.

[FIG. 25] A perspective explanatory view illustrating a state in which another liquid film is formed on the wafer.

[FIG. 26] A perspective view illustrating an appearance in which the solvent is supplied onto the wafer using a solvent supply nozzle according to another embodiment.

### BEST MODE FOR CARRYING OUT THE INVENTION

Hereinafter, an embodiment of the present invention will be described. FIG. 1 is an explanatory view illustrating the outline of a configuration of a substrate treatment system 1 including a coating treatment apparatus which performs a coating treatment method according to this embodiment. FIG. 2 and FIG. 3 are a front view and a rear view schematically illustrating the outline of an internal configuration of the substrate treatment system 1 respectively. Note that in this embodiment, a case in which the coating solution is a resist solution and the coating treatment apparatus is a resist coating apparatus which applies the resist solution to a substrate will be described as an example.

The coating treatment system 1 has, as illustrated in FIG. 1, a configuration in which a cassette station 10 into/out of which a cassette C housing a plurality of wafers W is transferred, a treatment station 11 including a plurality of various treatment apparatuses which perform predetermined treatments on the wafer W, and an interface station 13 which delivers the wafer W to/from an exposure apparatus 12 adjacent to the treatment station 11, are integrally connected.

In the cassette station 10, a cassette mounting table 20 is provided. The cassette mounting table 20 is provided with a plurality of cassette mounting plates 21 on which the cassettes C are mounted when the cassettes C are transferred in/out from/to the outside of the substrate treatment system 1.

In the cassette station 10, a wafer transfer apparatus 23 is provided which is movable on a transfer path 22 extending in an X-direction as illustrated in FIG. 1. The wafer transfer apparatus 23 is movable also in a vertical direction and around a vertical axis (in a θ-direction), and can transfer the wafer W between the cassette C on each of the cassette mounting plates 21 and a later-described delivery apparatus in a third block G3 in the treatment station 11.

In the treatment station 11, a plurality of, for example, four blocks G1, G2, G3, G4 are provided each including various apparatuses. For example, the first block G1 is provided on the front side (X-direction negative direction side in FIG. 1) in the treatment station 11, and the second block G2 is provided on the rear side (X-direction positive direction side in FIG. 1) in the treatment station 11. Further, the third block G3 is provided on the cassette station 10 side (Y-direction negative direction side in FIG. 1) in the treatment station 11, and the fourth block G4 is provided on the interface station 13 side (Y-direction positive direction side in FIG. 1) in the treatment station 11.

For example, in the first block G1, as illustrated in FIG. 2, a plurality of solution treatment apparatuses, for example, developing treatment apparatuses 30 each of which performs a developing treatment on the wafer W, lower anti-reflection film forming apparatuses 31 each of which forms an anti-reflection film (hereinafter, referred to as a “lower anti-reflection film”) at a lower layer of a resist film of the wafer W, resist coating apparatuses 32 each of which applies a resist solution onto the wafer W to form a resist film, and upper anti-reflection film forming apparatuses 33 each of which forms an anti-reflection film (hereinafter, referred to as an “upper anti-reflection film”) at an upper layer of the resist film of the wafer W, are arranged in order from the bottom.

For example, three apparatuses each of the developing treatment apparatus 30, the lower anti-reflection film forming apparatus 31, the resist coating apparatus 32, and the upper anti-reflection film forming apparatus 33 are arranged side by side in the horizontal direction. Note that the numbers and the arrangement of the developing treatment apparatuses 30, the lower anti-reflection film forming apparatuses 31, the resist coating apparatuses 32, and the upper anti-reflection film forming apparatuses 33 can be arbitrarily selected.

In the developing treatment apparatus 30, the lower anti-reflection film forming apparatus 31, the resist coating apparatus 32, and the upper anti-reflection film forming apparatus 33, for example, spin coating of applying a predetermined coating solution onto the wafer W is performed. In the spin coating, the coating solution is discharged, for example, from a coating nozzle onto the wafer W and the wafer W is rotated to diffuse the coating solution over the front surface of the wafer W. Note that the configuration of the resist coating apparatus 32 will be described later.

For example, in the second block G2, as illustrated in FIG. 3, thermal treatment apparatuses 40 each of which performs thermal treatments such as heating and cooling on the wafer W, adhesion apparatuses 41 each for enhancing adhesion between the resist solution and the wafer W, and edge exposure apparatuses 42 each of which exposes the outer peripheral portion of the wafer W, are arranged side by side in the vertical direction and in the horizontal direction. The numbers and the arrangement of the thermal treatment apparatuses 40, the adhesion apparatuses 41, and the edge exposure apparatuses 42 can also be arbitrarily selected.

For example, in the third block G3, a plurality of delivery apparatuses 50, 51, 52, 53, 54, 55, 56 are provided in order from the bottom. Further, in the fourth block G4, a plurality of delivery apparatuses 60, 61, 62 are provided in order from the bottom.

A wafer transfer region D is formed in a region surrounded by the first block G1 to the fourth block G4 as illustrated in FIG. 1. In the wafer transfer region D, for example, a plurality of wafer transfer apparatuses 70 are arranged each of which has a transfer arm movable, for example, in the Y-direction, the X-direction, the θ-direction, and the vertical direction. The wafer transfer apparatus 70 can move in the wafer transfer region D to transfer the wafer W to a predetermined apparatus in the first block G1, the second block G2, the third block G3 and the fourth block G4 therearound.

Further, in the wafer transfer region D, a shuttle transfer apparatus 80 is provided which linearly transfers the wafer W between the third block G3 and the fourth block G4.

The shuttle transfer apparatus 80 is configured to be linearly movable, for example, in the Y-direction in FIG. 3. The shuttle transfer apparatus 80 can move in the Y-direction while supporting the wafer W, and transfer the wafer W between the delivery apparatus 52 in the third block G3 and the delivery apparatus 62 in the fourth block G4.

As illustrated in FIG. 1, a wafer transfer apparatus 100 is provided adjacent on the X-direction positive direction side of the third block G3.

The wafer transfer apparatus 100 has a transfer arm that is movable, for example, in the X-direction, the θ-direction, and the vertical direction. The wafer transfer apparatus 100 can move up and down while supporting the wafer W to transfer the wafer W to each of the delivery apparatuses in the third block G3.

In the interface station 13, a wafer transfer apparatus 110 and a delivery apparatus 111 are provided. The wafer transfer apparatus 110 has a transfer arm that is movable, for example, in the Y-direction, the θ-direction, and the vertical direction. The wafer transfer apparatus 110 can transfer the wafer W to/from each of the delivery apparatuses in the fourth block G4, the delivery apparatus 111 and the exposure apparatus 12, for example, while supporting the wafer W by the transfer arm.

Next, the configuration of the above-described resist coating apparatus 32 will be described. The resist coating apparatus 32 has a treatment container 130 whose inside can be hermetically closed as illustrated in FIG. 4. A side surface of the treatment container 130 is formed with a transfer-in/out port (not illustrated) for the wafer W.

In the treatment container 130, a spin chuck 140 is provided as a substrate holding unit which holds and rotates the wafer W thereon. The spin chuck 140 can rotate at a predetermined speed, for example, by a chuck drive unit 141 such as a motor. Further, the chuck drive unit 141 is provided with, for example, a raising and lowering drive mechanism such as a cylinder so that the spin chuck 140 freely rises and lowers.

Around the spin chuck 140, a cup 142 is provided which receives and collects liquid splashing or dropping from the wafer W. A drain pipe 143 for draining the collected liquid and an exhaust pipe 144 for discharging the atmosphere in the cup 142 are connected to the lower surface of the cup 142.

As illustrated in FIG. 5, on an X-direction negative direction (the lower direction in FIG. 5) side of the cup 142, a rail 150 is formed which extends along a Y-direction (the right-left direction in FIG. 5). The rail 150 is formed, for example, from a Y-direction negative direction (left direction in FIG. 5) side outer position to a Y-direction positive direction (right direction in FIG. 5) side outer position of the cup 142. To the rail 150, three arms 151, 152, 153 are attached.

On the first arm 151, a resist solution supply nozzle 154 as a coating solution supply nozzle which supplies the resist solution as the coating solution is supported. The first arm 151 is movable on the rail 150 by means of a nozzle drive unit 155 as a first moving mechanism. This allows the resist solution supply nozzle 154 to move from a waiting section 156 provided at the Y-direction positive direction side outer position of the cup 142 to a waiting section 157 provided at the Y-direction negative direction side outer side of the cup 142 through a position above a center portion of the wafer W in the cup 142. Further, the first arm 151 freely rises and lowers by means of the nozzle drive unit 155 to be able to adjust the height of the resist solution supply nozzle 154. Note that as the resist solution in this embodiment, for example, an MUV resist, a KrF resist, an ArF resist or the like is used which is a resist whose viscosity is relatively low, approximately 1 to 300 cP.

On the second arm 152, a solvent supply nozzle 158 is supported which supplies a solvent. The second arm 152 is movable on the rail 150 by means of a nozzle drive unit 159 as a second moving mechanism. This allows the solvent supply nozzle 158 to move from a waiting section 160 provided on the Y-direction positive direction side outer side of the cup 142 to a position above the center portion of the wafer W in the cup 142. The waiting section 160 is provided at a Y-direction positive direction side of the waiting section 156. Further, the second arm 152 freely rises and lowers by means of the nozzle drive unit 159 to be able to adjust the height of the solvent supply nozzle 158. Note that as the solvent in this embodiment, for example, cyclohexanone being the solvent for the resist solution or the like is used. Further, the solvent does not necessarily need to be a solvent contained in the resist solution, and any solvent can be arbitrarily selected as long as it can appropriately diffuse the resist solution by pre-wet.

On the third arm 153, a dry gas nozzle 161 is supported which blows a dry gas to the wafer W. The third arm 153 is movable on the rail 150 by means of a nozzle drive unit 162 as a gas nozzle moving mechanism. This allows the dry gas nozzle 161 to move from a waiting section 163 provided on the Y-direction negative direction side outer side of the cup 142 to a position above the wafer W in the cup 142. The waiting section 163 is provided on the Y-direction negative direction side of the waiting section 157. Further, the third arm 153 freely rises and lowers by means of the nozzle drive unit 162 to be able to adjust the height of the dry gas nozzle 161. Note that as the dry gas, for example, a nitrogen gas, air dehumidified by a dehumidifier (not illustrated) or the like can be used.

The configurations of the developing treatment apparatus 30, the lower anti-reflection film forming apparatus 31, and the upper anti-reflection film forming apparatus 33 which are other solution treatment apparatuses are the same as that of the above-described resist coating apparatus 32 other than the shapes and the numbers of the nozzles and the solutions supplied from the nozzles are different, and therefore description thereof will be omitted.

The above substrate treatment system 1 is provided with a control unit 200 as illustrated in FIG. 1. The control unit 200 is composed of, for example, a computer which includes a program storage unit (not illustrated).

In the program storage unit, a program controlling the treatments on the wafer W in the substrate treatment system 1 is stored. Further, the program storage unit also stores a program for realizing a later-described substrate treatment in the substrate treatment system 1 by controlling the operations of the above-described various treatment apparatuses and a drive system of the transfer apparatuses. Note that the above-described programs may be ones which are recorded, for example, in a computer-readable storage medium H such as a computer-readable hard disk (HD), flexible disk (FD), compact disk (CD), magneto-optical disk (MO), or memory card, and installed from the storage medium into the control unit 200.

Next, a wafer treatment performed using the substrate treatment system 1 configured as described above will be described. FIG. 6 is a flowchart illustrating examples of main steps of the wafer treatment according to this embodiment. Besides, FIG. 7 is a time chart illustrating the rotation speed of the wafer W and operations of devices in the resist coating performed in the resist coating apparatus 32.

First, the cassette C housing a plurality of wafers W is transferred into the cassette station 10 of the substrate treatment system 1 and the wafers W in the cassette C are successively transferred by the wafer transfer apparatus 23 to the delivery apparatus 53 in the treatment station 11.

The wafer W is then transferred to the thermal treatment apparatus 40 in the second block G2 and subjected to a temperature regulation treatment. The wafer W is then transferred by the wafer transfer apparatus 70, for example, to the lower anti-reflection film forming apparatus 31 in the first block G1, in which a lower anti-reflection film is formed on the wafer W (Step S1 in FIG. 6). The wafer W is then transferred to the thermal treatment apparatus 40 in the second block G2, and heat-treated and temperature-regulated.

The wafer W is then transferred to the adhesion apparatus 41 and subjected to an adhesion treatment. The wafer W is then transferred to the resist coating apparatus 32 in the first block G1, in which a resist film is formed on the wafer W (Step S2 in FIG. 6).

Here, the resist coating treatment in the resist coating apparatus 32 will be described in detail. For the coating treatment of the resist, the wafer W is first suction-held on the upper surface of the spin chuck 140. Then, the solvent supply nozzle 158 is moved to a position above the center portion of the wafer W, and a solvent Q is supplied onto the wafer W as illustrated in FIG. 8 (time t₀ in FIG. 7). Subsequently, while the solvent is being supplied onto the wafer W or after the solvent Q is supplied onto the wafer W, the wafer W is rotated at a predetermined rotation speed, whereby a liquid film of the solvent Q is formed on the entire surface of the wafer W. Note that, in this embodiment, the solvent Q is supplied for 2 seconds from the solvent supply nozzle 158 at a flow rate of 50 to 90 mL/min while the wafer W is being rotated, for example, at 30 rpm (time t₁ in FIG. 7), and then the rotation speed of the wafer W is accelerated up to 2000 rpm, for example, at an acceleration of 10000 rpm/sec to diffuse the solvent Q over the entire surface of the wafer W. This forms a liquid film (first liquid film) with a film thickness of approximately more than 0 mm and less than 2 mm, approximately 4×10⁻⁵ mm in this embodiment, on the entire surface of the wafer W. Note that the film thickness of the first liquid film is adjusted, for example, by changing the time for keeping the rotation speed at 2000 rpm, and the rotation speed is kept at 2000 rpm, for example, for 2 seconds in this embodiment.

Note that in order to reduce the time required to bring the first liquid film to a desired thickness, for example, a dry gas may be sprayed as needed to the middle portion of the wafer W by the dry gas nozzle 161 as illustrated in FIG. 9 to adjust the film thickness of a first liquid film M1, in particular, at the middle portion.

Then, the solvent supply nozzle 158 is moved, for example, to a position above the outer peripheral portion of the wafer W as illustrated in FIG. 10, and the solvent Q is supplied onto the liquid film M1 from the solvent supply nozzle 158 while the wafer W is being rotated, for example, at a rotation speed of higher than 0 rpm and equal to or lower than a later-described first rotation speed, at 60 rpm the same as the first rotation speed in this embodiment (time t₂ in FIG. 7). This forms the first liquid film M1 of the solvent Q at the middle portion of the wafer W and forms a ring-shaped second liquid film M2 having a film thickness larger than that of the first liquid film M1 at the outer peripheral portion of the wafer W as illustrated in FIG. 11 (solvent liquid film formation step, Step T1 in FIG. 6). Here, the outer peripheral portion of the wafer W means a position separated from the center of the wafer W by about 30 mm to 100 mm in a radial direction, for example, when the diameter of the wafer W is 300 mm.

Next, as illustrated in FIG. 12, the resist solution supply nozzle 154 is moved to a position above the center portion of the wafer W and the resist solution R is supplied from the resist solution supply nozzle 154 onto the wafer W (coating solution supply step, Step T2 in FIG. 6 and time t₃ in FIG. 7). In this event, the rotation speed of the wafer W is the first rotation to speed, and 60 rpm as described above in this embodiment.

Then, the supply of the resist solution R from the resist solution supply nozzle 154 is continued, and at the point in time when the supply amount of the resist solution R reaches, for example, 0.1 mL, the rotation speed of the wafer W is accelerated from the first rotation speed to the second rotation speed (time t₄ in FIG. 7). The second rotation speed is preferably 1500 rpm to 4000 rpm and is, for example, 2500 rpm in this embodiment. Further, the acceleration of the wafer W at this time is about 10000 rpm/sec. The rotation speed of the wafer W reached the second rotation speed is kept at the second rotation speed for a predetermined time, for example, about 1 second in this embodiment (times t₅ to t₆ in FIG. 7). Further, during this time, the supply of the resist solution R from the resist solution supply nozzle 154 is also continued. Accelerating the wafer W to the second rotation speed as described above diffuses the resist solution R supplied to the center portion of the wafer W toward the outer peripheral portion of the wafer W (coating solution diffusion step, Step T3 in FIG. 6).

In this event, the wafer W has been subjected to the pre-wet treatment with the first liquid film M1, and therefore the resist solution R supplied onto the wafer W is quickly diffused toward the outer peripheral portion of the wafer W. When the resist solution R comes into contact with an inner peripheral end portion of the ring-shaped second liquid film M2 as illustrated in FIG. 12, the second liquid film M2 functions as a kind of wall with respect to the resist solution R and can suppress the diffusion of the resist solution R. This can minimize the resist solution R shaken off from the outer peripheral portion of the wafer W, and prevent decrease in film thickness of the resist film at the outer peripheral portion of the wafer W and occurrence of streak-shaped coating mottles. As a result, the resist solution R can be diffused uniformly within the wafer W to form a resist film uniformly within a plane.

Note that the supply of the solvent Q to the outer peripheral portion of the wafer W is stopped before the resist solution R is supplied to the center portion of the wafer W in this embodiment, but the supply of the resist solution R to the outer peripheral portion of the wafer W only needs to be stopped by the time when the resist solution R comes into contact with the second liquid film M2, and the timing for stop of supply can be arbitrarily set. If the supply of the solvent Q from the solvent supply nozzle 158 to the outer peripheral portion of the wafer W is continued at the time when the resist solution R is diffused, the resist solution R diffused toward the outer periphery of the wafer W and the solvent Q mix together, whereby the resist solution R is diluted. Then, the most of the diluted resist solution R does not fix on the wafer W but is wastefully shaken off from the outer peripheral portion of the wafer W. Accordingly, it is preferable to stop the supply of the solvent Q by the time when the resist solution R comes into contact with the second liquid film M2.

After the wafer W is rotated for the predetermined time (times t₅ to t₆ in FIG. 7) at the second rotation speed, the supply of the resist solution R from the resist solution supply nozzle 154 is stopped, and the rotation speed of the wafer W is decelerated down to a third rotation speed that is lower than the second rotation speed and higher than the first rotation speed concurrently with the stop of supply of the resist solution R. The third rotation speed is preferably set to approximately 100 rpm to 800 rpm, for example, 100 rpm in this embodiment. Note that “concurrently with the stop of supply of the resist solution R” includes before and after the point in time when the rotation speed of the wafer W has already started deceleration and reaches the third rotation speed at the time when the supply of the resist solution R is stopped (time t₆ in FIG. 7). Besides, the acceleration at the time when decelerating the rotation speed from the second rotation speed to the third rotation speed is 30000 rpm/sec.

Thereafter, the wafer W is rotated at the third rotation speed for a predetermined time, for example, about 0.2 seconds, and then accelerated up to a fourth rotation speed that is higher than the third rotation speed and lower than the second rotation speed (time t₇ in FIG. 7). The fourth rotation speed is preferably set to approximately 1000 rpm to 2000 rpm, for example, 1700 rpm in this embodiment. Then, the resist film is dried by rotating the wafer W at the fourth rotation speed for a predetermined time, for example, about 20 seconds (Step T4 in FIG. 6).

Thereafter, a solvent is discharged as a rinse solution from a not-illustrated rinse nozzle to a rear surface of the wafer W to clean the rear surface of the wafer W (Step T5 in FIG. 6). With this, a series of coating treatment in the resist coating apparatus 32 ends.

After the resist film is formed on the wafer W, the wafer W is then transferred to the upper anti-reflection film forming apparatus 33 in the first block G1, in which an upper anti-reflection film is formed on the wafer W (Step S3 in FIG. 6). The wafer W is then transferred to the thermal treatment apparatus 40 in the second block G2, and subjected to a heat treatment. The wafer W is then transferred to the edge exposure apparatus 42 and subjected to edge exposure processing (Step S4 in FIG. 6).

Then, the wafer W is transferred by the wafer transfer apparatus 100 to the delivery apparatus 52, and transferred by the shuttle transfer apparatus 80 to the delivery apparatus 62 in the fourth block G4. The wafer W is then transferred by the wafer transfer apparatus 110 in the interface station 13 to the exposure apparatus 12 and subjected to exposure processing in a predetermined pattern (Step S5 in FIG. 6).

Then, the wafer W is transferred by the wafer transfer apparatus 70 to the thermal treatment apparatus 40 and subjected to a post-exposure bake treatment. Thus, the resist is subjected to a deprotection reaction with an acid generated at an exposed portion of the resist film. The wafer W is thereafter transferred by the wafer transfer apparatus 70 to the developing treatment apparatus 30 and subjected to a developing treatment (Step S6 in FIG. 6).

After the developing treatment ends, the wafer W is transferred to the thermal treatment apparatus 40 and subjected to a post-bake treatment (Step S7 in FIG. 6). The wafer W is then temperature-regulated by the thermal treatment apparatus 40. The wafer W is thereafter transferred to the cassette C on a predetermined cassette mounting plate 21 via the wafer transfer apparatus 70 and the wafer transfer apparatus 23, with which a series of photolithography process ends.

According to the above embodiment, the ring-shaped second liquid film M2 having a film thickness larger than that of the first liquid film M1 formed at the middle portion of the wafer W is formed at the outer peripheral portion of the wafer W of the solvent Q, so that at the time when diffusing the resist solution R supplied to the center portion of the wafer W over the wafer W, the second liquid film M2 can function as a kind of wall with respect to the resist solution R to suppress the diffusion of the resist solution R. Therefore, even if the viscosity of the resist solution R is a low viscosity such as about several cP, the resist solution R shaken off from the outer peripheral portion of the wafer W can be minimized to prevent a decrease in film thickness of the resist film at the outer peripheral portion of the wafer W and occurrence of streak-shaped coating mottles. As a result, the resist solution R can be diffused uniformly within the wafer W to form a resist film uniformly within a plane.

Note that the rotation speed of the wafer W is accelerated up to, for example, about 2000 rpm when forming the first liquid film M1 in the above embodiment, but the method of forming the first liquid film M1 is not limited to the content of this embodiment, and an arbitrary method can be selected as long as the method can form a liquid film of the solvent Q having a desired thickness at the middle portion of the wafer W. For example, the film thickness of the first liquid film M1 may be adjusted by keeping the rotation speed of the wafer W at the rotation speed at the time when supplying the solvent Q to the center portion of the wafer W, approximately 30 rpm in this embodiment after supplying the solvent Q to the center portion of the wafer W, and adjusting the time during which the wafer W is rotated. Alternatively, as has been described, the film thickness of the first liquid film M1 may be adjusted by spraying the dry gas to the middle portion of the wafer W by the dry gas nozzle 161.

In the case where the film thickness of the first liquid film M1 is adjusted by the dry gas, the shape of the dry gas nozzle 161 supplying the dry gas is not limited to the content of this embodiment, but an arbitrary method can be selected as long as the method can form a liquid film having a desired thickness at the middle portion of the wafer W by the solvent Q. For example, the film thickness, in particular at the middle portion, of the first liquid film M1 may be adjusted by providing a long dry gas nozzle 170 extending in a diameter direction of the wafer W as illustrated in FIG. 13 in the resist coating apparatus 32, and supplying the dry gas from the dry gas nozzle 170 toward the wafer W while rotating the wafer W. In this case, the length in the longer direction of the dry gas nozzle 170 may be set to a length of about 60 to 200 mm. Alternatively, the length in the longer direction of the dry gas nozzle 170 may be halved to about 30 to 100 mm, and the dry gas nozzle 170 may be disposed at a position covering the center portion of the wafer W and eccentric from the center of the wafer W as illustrated in FIG. 14 to supply the dry gas to the middle portion of the wafer W.

Alternatively, the diameter of the dry gas nozzle 161 may be set, for example, to about 60 to 200 mm in a manner to cover a portion above the middle portion of the wafer W, and the dry gas nozzle 161 having such a large diameter may supply the dry gas to the middle portion of the wafer W. Further, it can be also suggested to supply the dry gas to the middle portion of the wafer W by an almost disk-shaped dry gas nozzle 171 having a diameter of about 60 to 200 mm and having a plurality of gas supply ports (not illustrated) formed at its lower surface as illustrated in FIG. 15.

Besides, for adjusting the film thickness of the first liquid film M1, what is sprayed to the wafer W does not necessarily need to be the dry gas. As illustrated in FIG. 16, for example, a heater 180 may be provided in the treatment container 130 of the resist coating apparatus 32 and above the spin chuck 140 to heat a downward flow formed in the treatment container 130 by the exhaust pipe 144 provided at the cup 142, for example, to equal to or higher than the volatilization temperature of the solvent Q. By the heating of the downward flow, the solvent Q on the wafer W can volatilize by the downward flow, thereby adjusting the film thickness of the first liquid film M1. Besides, the dry gases supplied from the dry gas nozzles 161, 170, 171 may be heated to equal to or higher than the volatilization temperature of the solvent Q.

Note that though the first liquid film M1 is formed first on the entire surface of the wafer W and then the second liquid film M2 is formed by supplying the solvent Q to the outer peripheral portion of the wafer W in the above embodiment, an arbitrary formation order of the first liquid film M1 and the second liquid film M2 may be selected as long as the second liquid film M2 having a film thickness larger than that of the first liquid film M1 can be formed at the outer peripheral portion of the wafer W. For example, the ring-shaped second liquid film M2 is formed first by supplying the solvent Q to the outer peripheral portion of the wafer W with the wafer W being rotated as illustrated in FIG. 17, and then the first liquid film M1 may be formed at the middle portion of the wafer W by supplying a small amount of the solvent Q from the solvent supply nozzle 158 to the center portion of the wafer W as illustrated in FIG. 18. Alternatively, a plurality of solvent supply nozzles 158 may be provided in the resist coating apparatus 32, and the solvent Q is supplied concurrently to the center portion and the outer peripheral portion of the wafer W as illustrated in FIG. 19 to form the first liquid film M1 and the second liquid film M2.

Note that the state where the first liquid film M1 and the second liquid film M2 are not in contact with each other is illustrated in FIG. 18 and FIG. 19, and the first liquid film M1 and the second liquid film M2 do not necessarily need to be in contact with each other according to the present inventors. As described above, it has been confirmed that as long as the liquid film M2 having a larger film thickness than that of the first liquid film M1 is formed at the outer peripheral portion of the wafer W, the second liquid film M2 functions as a wall when the resist solution R supplied on the first liquid film M1 is diffused toward the outer peripheral portion of the wafer W and can form a resist film uniformly within a plane.

Note that the liquid-form solvent Q is supplied from the solvent supply nozzle 158 in the above embodiment, but the solvent Q does not necessarily need to be supplied in the liquid form and, for example, vapor or mist of the solvent Q may be supplied. For example, the first liquid film M1 may be formed at the middle portion of the wafer W by disposing a solvent supply nozzle 190 having the same configuration as that of the above-described dry gas nozzle 171 having an almost disk shape at a position above the middle portion of the wafer W as illustrated in FIG. 20, and supplying vapor or mist of the solvent Q from the solvent supply nozzle 190. The solvent supply nozzle 190 is moved by not-illustrated another moving mechanism. Note that in the case of supplying vapor of the solvent Q, it is preferable to supply vapor heated to a temperature higher than the temperature of the atmosphere in the treatment container 130 of the resist coating apparatus 32, from the solvent supply nozzle 190. This allows the temperature of the vapor of the solvent Q to lower and condense on the front surface of the wafer W to thereby form the first liquid film M1 having the desired film thickness at the middle portion of the wafer W. Then, after the formation of the first liquid film M1, the solvent Q is supplied from the solvent supply nozzle 158 to the outer peripheral portion of the wafer W to form the second liquid film M2. Note that also in the case of forming the first liquid film M1 by the solvent supply nozzle 190, it is also adoptable to first form the second liquid film M2 and then form the first liquid film M1.

Besides, when forming the first liquid film M1, for example, an almost disk-shaped template 191 having a flat lower surface may be disposed at a position above the middle portion of the wafer W as illustrated in FIG. 21, and the template 191 may be brought into contact with the upper surface of the wafer W as illustrated in FIG. 22 with the solvent Q applied to have a film thickness smaller than that of the second liquid film M2 on the lower surface of the template 191. After the contact with the wafer W, the template 191 can be lifted up to form the first liquid film at the middle portion of the wafer W as illustrated in FIG. 23. The template 191 is configured to be movable by a not-illustrated template moving mechanism. After the formation of the first liquid film M1 using the template 191, the solvent Q is supplied from the solvent supply nozzle 158 to the outer peripheral portion of the wafer W to form the second liquid film M2.

Note that though the appearances using the template 191 having a diameter smaller than that of the wafer W are illustrated in FIG. 21, FIG. 22,

FIG. 23, the diameter of the template 191 or the diameter of the solvent Q to be applied to the template 191 only needs to be larger than the diameter of the first liquid film M1 to be formed on the wafer W and can be arbitrarily set.

Though the diffusion of the resist solution R is suppressed by making the film thickness of the second liquid film M2 formed at the outer peripheral portion of the wafer W larger than the film thickness of the first liquid film formed at the middle portion of the wafer W in the above embodiment, for example, a plurality of other liquid films M3 in concentric circles having almost the same film thickness may be formed on the wafer W as illustrated in FIG. 24, FIG. 25 from the viewpoint of suppressing the resist solution R. The present inventors have confirmed that, for example, regions where the other liquid films M3 are not formed, in other words, regions that have not been subjected to pre-wet treatment with the solvent Q are formed, for example, in concentric circle shapes, thereby suppressing excessive diffusion of the resist solution R and providing the same effect as that in the case of forming the first liquid film M1 and the second liquid film M2.

The other liquid films M3 as describe above can be realized, for example, by disposing a dry gas nozzle 193 provided with a plurality of discharge ports 192, at a position above the wafer W with the liquid film having the predetermined film thickness formed thereon as illustrated in FIG. 24, and supplying the dry gas from the discharge ports 192, for example, in a state where the wafer W is being rotated. Note that for forming the other liquid films M3 by the dry gas nozzle 193, for example, the dry gas nozzle 193 may be rotated using the center portion of the wafer W as a support point in a state where the wafer W is stopped.

For forming the ring-shaped second liquid film M2 on the wafer W, the solvent Q is supplied to the outer peripheral portion of the wafer W while the wafer W is being rotated at the predetermined rotation speed in the above embodiment, the method of forming the liquid film of the solvent Q into the ring shape is not limited to the content of this embodiment. For example, a supporting arm 211 as a supporting unit, which can rotate the solvent supply nozzles 158 by a rotation drive mechanism 210 using the vertical axis passing through the center axis of the wafer W as a rotation axis as illustrated in FIG. 26, may support the solvent supply nozzles 158, and move the solvent supply nozzles 158 along the outer peripheral portion of the wafer W while the wafer W is standing still. Supplying the solvent Q in the state where the wafer W is stopped, avoids centrifugal force from acting on the solvent Q, so that the shape of the second liquid film M2 can be maintained in an excellent ring shape. As a result, the diffusion of the resist solution R at the outer peripheral portion of the wafer W can be made more uniform. The method of forming the ring-shaped liquid film of the solvent Q with the wafer W stopped as described above is effective in particular in the case where the diameter of the wafer W is large such as a 450 mm wafer and the circumferential speed is high at outer peripheral portion of the wafer W.

Note that the state in which the supporting arm 211 is provided with two solvent supply nozzles 158 is illustrated in FIG. 26. Providing a plurality of solvent supply nozzles 158 as described above makes it possible to decrease the rotation angle of the supporting arm 211 when forming the liquid film of the solvent Q into the ring-shape, thereby improving the throughput of the wafer treatment. More specifically, in the case where two solvent supply nozzles 158 are provided to face each other, the solvent Q can be supplied to the whole circumference of the wafer W by rotating the supporting arm 211 only by 180 degrees. Further, in the case where n (n is an integer of 3 or more) solvent supply nozzles 158 are provided, it is only necessary to rotate the supporting arm 211 only by (360/n) degrees according to the number of the solvent supply nozzle 158 provided.

Further, in the case of rotating the solvent supply nozzles 158 by the supporting arm 211, the wafer W may be rotated in a direction opposite to the rotation direction of the supporting arm 211. This increases the relative rotation speed of the solvent supply nozzles 158 relative to the wafer W, thereby making it possible to form the second liquid film M2 more quickly.

### EXAMPLES

As an example, a test of applying a resist solution onto a wafer W by the coating treatment method according to this embodiment was carried out using an ArF resist having a viscosity of 1.0 cP as the resist solution R and cyclohexanone as the solvent Q. In this case, the film thickness of the first liquid film M1 was changed by changing the supply amount of the resist solution R by an increment of 0.05 mL between 0.20 mL and 0.30 mL, and changing the time during which the wafer W was rotated at a rotation speed of 2000 rpm between times t₁ to t₂ in FIG. 7 for forming the first liquid film M1 to 2 seconds, 5 seconds, and 8 seconds.

Further, as a comparative example, the same test was carried out also in the case of uniformly pre-wetting the entire surface of the wafer W with the solvent Q as in the conventional art, and then supplying the resist solution R to the center portion of the wafer W. Note that the same resist solution R and the same solvent Q were used also in the comparative example.

As a result of the test, in the comparative example, the film thickness uniformity of the resist film within the wafer W was a desired value in the case of setting the supply amount of the resist solution R to 0.20 mL, but coating mottles possibly caused from deficiency in supply amount of the resist solution R were found at the outer peripheral portion of the wafer W.

On the other hand, in any of the cases of setting the supply amount of the resist solution R to 0.20 mL to 0.30 mL when setting the time during which the wafer W was rotated at a rotation speed of 2000 rpm to 2 seconds and 5 seconds using the coating treatment method according to this embodiment, the film thickness uniformity within the wafer W was ensured, and the coating mottles at the outer peripheral portion of the wafer W as those found in the comparative example were not found. In addition, it was confirmed that the film thickness uniformity within the wafer W was improved in the case of setting the rotation time to 5 seconds more than in the case of setting the rotation time to 2 seconds. It is considered that making the film thickness of the first liquid film M1 smaller suppresses excessive diffusion of the resist solution R at the middle portion of the wafer W to thereby suppress a decrease in film thickness of the resist film at the outer peripheral portion of the wafer W.

In the case of setting the time during which the wafer W was rotated at a rotation speed of 2000 rpm to 8 seconds, the film thickness uniformity of the resist film within the wafer W was a desired value, but coating mottles possibly caused from deficiency in supply amount of the resist solution R were found at the outer peripheral portion of the wafer W. It is considered that the rotation time of the wafer W was long and the most of the solvent Q was shaken off from the outer peripheral portion of the wafer W, and as a result, the first liquid film M1 was not appropriately formed. In other words, it is considered that the coating treatment method according to this embodiment was not performed. Accordingly, from the result, it was confirmed that a coating film uniform within the wafer W can be formed by the coating treatment method according to this embodiment. Note that according to the present inventors, the first liquid film M1 only needs to be formed to prevent the front surface of the wafer W from getting dry, and the lower limit value of the film thickness of the first liquid film M1 only needs to be more than 0 mm as has been described. Further, the upper limit value of the first liquid film M1 is preferably set to less than 2 mm as has been described from the viewpoint of suppressing excessive diffusion of the resist solution R at the middle portion of the wafer W.

A preferred embodiment of the present invention has been described above with reference to the accompanying drawings, but the present invention is not limited to the embodiment. It should be understood that various changes and modifications are readily apparent to those skilled in the art within the scope of the spirit as set forth in claims, and those should also be covered by the technical scope of the present invention. The present invention is not limited to the embodiment but can take various forms. The present invention is also applicable to the case where the substrate is a substrate other than the wafer, such as an FPD (Flat Panel Display), a mask reticle for a photomask or the like.

### INDUSTRIAL APPLICABILITY

The present invention is useful in applying a coating solution onto a substrate.

### [Explanation of Codes]

1 substrate treatment system

30 developing treatment apparatus

31 lower anti-reflection film forming apparatus

32 resist coating apparatus

33 upper anti-reflection film forming apparatus

40 thermal treatment apparatus

41 adhesion apparatus

42 edge exposure apparatus

140 spin chuck

154 resist solution supply nozzle

158 solvent supply nozzle

161 dry gas nozzle

200 control unit

Q solvent

M1 first liquid film

M2 second liquid film

R resist solution

W wafer

What is claimed:

1. A coating treatment method of applying a coating solution onto a substrate, comprising:
a solvent liquid film formation step of forming a first liquid film of a solvent at a middle portion of the substrate and forming a ring-shaped second liquid film having a film thickness larger than a film thickness of the first liquid film of the solvent at an outer peripheral portion of the substrate;
a coating solution supply step of supplying the coating solution to a center portion of the substrate while rotating the substrate at a first rotation speed; and
a coating solution diffusion step of diffusing the coating solution on the substrate by rotating the substrate at a second rotation speed higher than the first rotation speed while supplying the coating solution.

2. The coating treatment method according to claim 1,
wherein in the solvent liquid film formation step,
the first liquid film is formed by supplying the solvent to the middle portion of the substrate and thereafter rotating the substrate at a predetermined rotation speed to shake off the solvent, and
then the second liquid film is formed by supplying the solvent from a solvent supply nozzle located at the outer peripheral portion of the substrate with the substrate being rotated.

3. The coating treatment method according to claim 2,
wherein in the formation of the first liquid film, a dry gas is sprayed to the middle portion of the substrate while the substrate is being rotated at the predetermined rotation speed to shake off the solvent.

4. The coating treatment method according to claim 3,
wherein the dry gas is heated to equal to or higher than a volatilization temperature of the solvent.

5. The coating treatment method according to claim 1,
wherein in the solvent liquid film formation step,
the first liquid film is formed by supplying at least either vapor or mist of the solvent to the middle portion of the substrate, and
the second liquid film is formed by supplying the solvent from a solvent supply nozzle located at the outer peripheral portion of the substrate with the substrate being rotated.

6. The coating treatment method according to claim 1,
wherein in the solvent liquid film formation step,
the first liquid film is formed by bringing a template having the solvent in a film thickness smaller than the film thickness of the second liquid film applied on a front surface thereof into contact with a front surface of the middle portion of the substrate, and
the second liquid film is formed by supplying the solvent from a solvent supply nozzle located at the outer peripheral portion of the substrate with the substrate being rotated.

7. The coating treatment method according to claim 2,
wherein in the solvent liquid film formation step, the solvent is supplied from the solvent supply nozzle at a position separated from a center of the substrate by 30 mm to 100 mm in a radial direction.

8. A coating treatment method of applying a coating solution onto a substrate, comprising:
a solvent liquid film formation step of forming a liquid film of a solvent at a middle portion of the substrate and forming a ring-shaped liquid film at an outer peripheral portion of the substrate by forming a liquid film of the solvent by supplying the solvent to the middle portion of the substrate and thereafter rotating the substrate at a predetermined rotation speed to shake off the solvent, and then spraying a dry gas to a position deviated from the middle portion of the substrate with the substrate being rotated to remove the solvent at the position deviated from the middle portion of the substrate;
a coating solution supply step of supplying the coating solution to a center portion of the substrate while rotating the substrate at a first rotation speed; and
a coating solution diffusion step of diffusing the coating solution on the substrate by rotating the substrate at a second rotation speed higher than the first rotation speed while supplying the coating solution.

9. The coating treatment method according to claim 1,
wherein a film thickness of the first liquid film is more than 0 mm and less than 2 mm.

10. A computer-readable storage medium storing a program running on a computer of a control unit controlling a coating treatment apparatus to cause the coating treatment apparatus to execute a coating treatment method of applying a coating solution onto a substrate,
coating treatment method comprising:
a solvent liquid film formation step of forming a first liquid film of a solvent at a middle portion of the substrate and forming a ring-shaped second liquid film having a film thickness larger than a film thickness of the first liquid film of the solvent at an outer peripheral portion of the substrate;
a coating solution supply step of supplying the coating solution to a center portion of the substrate while rotating the substrate at a first rotation speed; and
a coating solution diffusion step of diffusing the coating solution on the substrate by rotating the substrate at a second rotation speed higher than the first rotation speed while supplying the coating solution.

11. A coating treatment apparatus for applying a coating solution onto a substrate, comprising:
a substrate holding unit that holds and rotates the substrate;
a coating solution supply nozzle that supplies the coating solution onto the substrate;
a solvent supply nozzle that supplies a solvent onto the substrate;
a first moving mechanism that moves the coating solution supply nozzle;
a second moving mechanism that moves the solvent supply nozzle; and
a control unit configured to control the substrate holding unit, the coating solution supply nozzle, the solvent supply nozzle, the first moving mechanism, and the second moving mechanism so as to:
form a first liquid film of the solvent at a middle portion of the substrate and form a ring-shaped second liquid film having a film thickness larger than a film thickness of the first liquid film of the solvent at an outer peripheral portion of the substrate;
supply the coating solution to a center portion of the substrate while rotating the substrate at a first rotation speed; and
diffuse the coating solution on the substrate by rotating the substrate at a second rotation speed higher than the first rotation speed while supplying the coating solution.

12. The coating treatment apparatus according to claim 11, further comprising:
a dry gas nozzle that sprays a dry gas onto the substrate; and
a third moving mechanism that moves the dry gas nozzle.

13. The coating treatment apparatus according to claim 11, further comprising:
another solvent supply nozzle that supplies vapor or mist of the solvent; and
another moving mechanism that moves the another solvent supply nozzle.

14. The coating treatment apparatus according to claim 11, further comprising:
a template having the solvent in a film thickness smaller than the film thickness of the second liquid film applied on a front surface thereof and, in such a state, brought into contact with a front surface of the middle portion of the substrate to form the first liquid film at the middle portion of the substrate; and
a template moving mechanism that moves the template.
